(19) United States
(12) Patent Application Publication
(10) Pub. No.: US 2025/0194089 A1
(43) Pub. Date: Jun. 12, 2025

(54) MEMORY DEVICE AND MANUFACTURING METHOD OF THE MEMORY DEVICE

(71) Applicant: SK hynix Inc., Icheon-si Gyeonggi-do (KR)

(72) Inventors: Hyun Kyu LEE, Icheon-si Gyeonggi-do (KR); Sun Kak HWANG, Icheon-si Gyeonggi-do (KR); Sung Soon KIM, Icheon-si Gyeonggi-do (KR)

(73) Assignee: SK hynix Inc., Icheon-si Gyeonggi-do (KR)

(21) Appl. No.: 18/656,237

(22) Filed: May 6, 2024

(30) Foreign Application Priority Data
Dec. 12, 2023 (KR) 10-2023-0179620

(51) Int. Cl. H10B 43/27; H10B 43/10

(52) U.S. Cl. CPC H10B 43/27; H10B 43/10

(57) ABSTRACT

The present disclosure relates a method of manufacturing a memory device. A method of manufacturing a memory device includes forming a stack structure including first material layers alternately stacked with second material layers, forming a channel layer including amorphous silicon in an opening extending through the stack structure, converting a first part of the channel layer into single crystalline silicon, doping the first part of the channel layer with a conductive material, doping a second part different from the first part of the channel layer with the conductive material, and converting the second part of the channel layer into polycrystalline silicon using the conductive material.

### CROSS-REFERENCE TO RELATED APPLICATION

The present application claims priority under 35 U.S.C. § 119 (a) to Korean patent application number 10-2023-0179620 filed on Dec. 12, 2023, in the Korean Intellectual Property Office, the entire contents of which application is incorporated herein by reference.

### BACKGROUND

### 1. Technical Field

Various embodiments of the present disclosure generally relate to a memory device and a manufacturing method of the memory device, and more particularly, to a memory device including a three-dimensional memory block and a method of manufacturing the memory device.

### 2. Related Art

A memory device may include a non-volatile memory device in which stored data is retained even when power supply is interrupted. The non-volatile memory device may be classified as a two-dimensional structure or a three-dimensional structure according to a structure in which memory cells are arranged. Memory cells of a non-volatile memory device having a two-dimensional structure may be arranged in a single layer on a substrate, and memory cells of a non-volatile memory device having a three-dimensional structure may be stacked in a vertical direction on the substrate. Because a degree of integration of the non-volatile memory device having the three-dimensional structure is higher than the degree of integration of the non-volatile memory device having the two-dimensional structure, electronic devices using non-volatile memory devices having a three-dimensional structure have recently been increasing in popularity.

### SUMMARY

According to an embodiment, a method of manufacturing a memory device may include forming a stack structure including first material layers alternately stacked with second material layers, forming a channel layer including amorphous silicon in an opening extending through the stack structure, converting a first part of the channel layer into single crystalline silicon, doping the first part of the channel layer with a conductive material, doping a second part of the channel layer different from the first part of the channel layer with the conductive material, and converting the second part of the channel layer into polycrystalline silicon using the conductive material.

According to an embodiment, a memory device may include a stack structure and a channel layer formed in an opening extending through the stack structure, wherein the channel layer includes a first part including single crystalline silicon and a second part including polycrystalline silicon, wherein the first part is adjacent to the second part.

According to an embodiment, a method may include forming an opening extending through a stack structure; forming a channel layer including amorphous silicon in the opening; converting a first part of the channel layer into single crystalline silicon; doping the first part of the channel layer and a second part of the channel layer with a conductive material, wherein the second part is adjacent to the first part; and converting the second part of the channel layer into polycrystalline silicon using the conductive material.

### BRIEF DESCRIPTION OF THE DRAWINGS

FIG. 1 is a diagram illustrating a memory device according to an embodiment of the present disclosure;

FIG. 2 is a diagram illustrating memory blocks of a memory device according to an embodiment of the present disclosure;

FIG. 3 is a plan view illustrating a layout of a memory device according to an embodiment of the present disclosure;

FIG. 4 is a cross-sectional view of a memory device according to an embodiment of the present disclosure;

FIG. 5A through FIG. 5I are diagrams illustrating cross-sectional views of a memory device formed utilizing a method of manufacturing the memory device according to an embodiment of the present disclosure;

FIG. 6 is a diagram illustrating an embodiment of a memory card system including a memory device according to an embodiment of the present disclosure; and

FIG. 7 is a diagram illustrating an embodiment of a solid state drive (SSD) system including a plurality of memory devices according to an embodiment of the present disclosure.

### DETAILED DESCRIPTION

Specific structural or functional descriptions described in the present disclosure are examples that describe embodiments according to the concepts of the present disclosure. Embodiments according to the concepts of the present disclosure may be implemented in various forms and should not be construed as being limited to the specific embodiments set forth in the present disclosure.

Embodiments of the present disclosure are described in detail with reference to the accompanying drawings to describe details sufficient to allow those skilled in the art to readily implement the technical aspects of the present disclosure. The cross-hatching throughout the figures illustrates corresponding or similar areas between the figures rather than indicating the materials for the areas.

Terms such as “under,” “over,” “upper,” “lower,” “left,” “right,” “down,” “downwards,” and other terms implying spatial relationship are provided only for the purpose of ease of description or reference to a drawing and are not otherwise limiting.

Various embodiments relate to a memory device capable of increasing a current flowing in memory cells and a method of manufacturing the memory device.

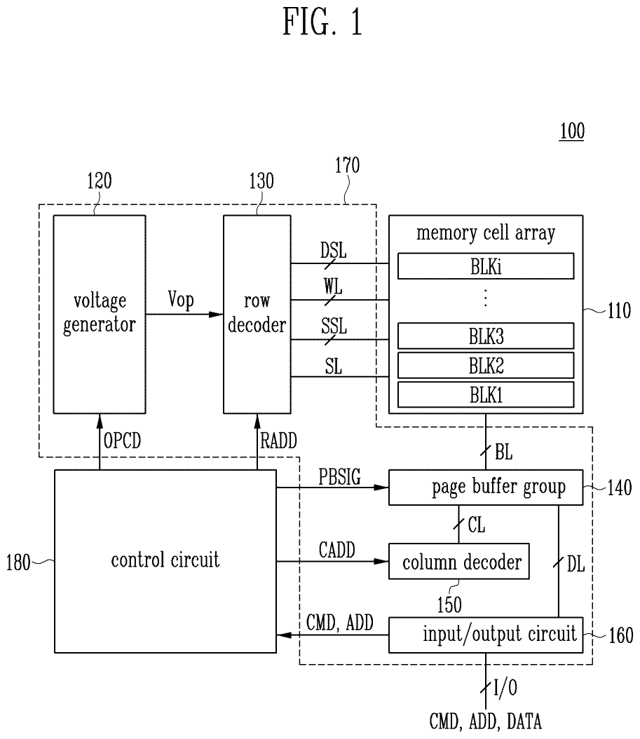

FIG. 1 is a diagram illustrating a memory device 100 according to an embodiment of the present disclosure.

Referring to FIG. 1, the memory device 100 includes a memory cell array 110, a peripheral circuit 170, and a control circuit 180.

The memory cell array 110 includes memory blocks BLK1 through BLKi, where i is a positive integer. Each of the first memory block BLK1 through the ith memory block BLKi includes memory cells capable of storing data. Drain select lines DSL, word lines WL, source select lines SSL, and a source line SL are coupled to each of the memory blocks BLK1 through BLKi, and bit lines BL are commonly coupled to the memory blocks BLK1 to BLKi.

The memory blocks BLK1 through BLKi have a three-dimensional structure. Memory blocks having a three-dimensional structure may include memory cells stacked, for example, in a vertical direction on a substrate.

A single memory cell may store one-bit data, two-bit data, three-bit data, four-bit data, five-bit data, and so forth according to a program method. For example, a method in which one-bit data is stored in one memory cell is referred to as a single-level cell (SLC) method, and a method in which two-bit data is stored in one memory cell is referred to as a multi-level cell (MLC) method. A method in which three-bit data is stored in one memory cell is referred to as a triple-level cell (TLC) method, and a method in which four-bit data is stored in one memory cell is referred to as a quad-level cell (QLC) method.

The peripheral circuit 170 is configured to perform a program operation that stores data in the memory cell array 110, a read operation that outputs data stored in the memory cell array 110, and an erase operation that erases data stored in the memory cell array 110. For example, the peripheral circuit 170 includes a voltage generator 120, a row decoder 130, a page buffer group 140, a column decoder 150, and an input/output circuit 160.

The voltage generator 120 generates various operating voltages Vop used during a program operation, a read operation, or an erase operation in response to an operation code OPCD. For example, the voltage generator 120 may be configured to generate program voltages, turn-on voltages, turn-off voltages, negative voltages, pre-charge voltages, verify voltages, read voltages, pass voltages, or erase voltages in response to the operation code OPCD. The operating voltages Vop generated by the voltage generator 120 are applied to the drain select lines DSL, the word lines WL, the source select lines SSL, and the source line SL of a selected memory block by the row decoder 130.

The program voltages are applied to a selected word line among the word lines WL during a program operation, and are used to increase threshold voltages of memory cells coupled to the selected word line. The turn-on voltages are applied to the drain select lines DSL and the source select lines SSL and are used to turn on drain select transistors and source select transistors. The turn-off voltages are applied to the drain select lines DSL and the source select lines SSL and are used to turn off the drain select transistors and the source select transistors. For example, the turn-off voltages may be set to 0V. The pre-charge voltages may be higher than 0V, and may be applied to the bit lines BL during a read operation. The verify voltages are used during a verify operation to determine whether threshold voltages of selected memory cells are increased to a target level. The verify voltages may be set to various levels according to the target level and may be applied to the selected word line.

The read voltages are applied to the selected word line during a read operation of the selected memory cells. For example, the read voltages may be set to various levels according to a program method of the selected memory cells. The pass voltages are applied to unselected word lines among the word lines WL during a program or read operation and are used to turn on memory cells coupled to the unselected word lines. The erase voltages are used during an erase operation to erase the memory cells included in the selected memory block and are applied to the source line SL.

The row decoder 130 is configured to transfer the operating voltages Vop to the drain select lines DSL, the word lines WL, the source select lines SSL, and the source line SL that are coupled to the selected memory block according to a row address RADD. For example, the row decoder 130 is coupled to the voltage generator 120 through global lines and is coupled to the memory blocks BLK1 through BLKi through the drain select lines DSL, the word lines WL, the source select lines SSL, and the source line SL.

The page buffer group 140 includes a plurality (i) of page buffers (not shown) respectively coupled to the memory blocks BLK1 through BLKi. The page buffers (not shown) are coupled to the memory blocks BLK1 through BLKi through the bit lines BL. During a read operation, the page buffers (not shown) sense a current or a voltage of the bit lines BL that varies according to the threshold voltages of the selected memory cells and temporarily stores sensed data in response to page buffer control signals PBSIG.

The column decoder 150 is configured to facilitate transfer of data between the page buffer group 140 and the input/output circuit 160 in response to a column address CADD. For example, the column decoder 150 is coupled to the page buffer group 140 through column lines CL and transfers enable signals through the column lines CL. The page buffers (not shown) included in the page buffer group 140 receive or output data through data lines DL to the input/output circuit 160 in response to the enable signals.

The input/output circuit 160 is configured to receive or output a command CMD, an address ADD, and data through input/output lines I/O. For example, the input/output circuit 160 transfers the command CMD and the address ADD, which are received from an external controller, to the control circuit 180 through the input/output lines I/O, and transfers data DATA received from the external controller to the page buffer group 140 through the input/output lines I/O. In addition, the input/output circuit 160 outputs data DATA transferred from the page buffer group 140 to the external controller through the input/output lines I/O.

The control circuit 180 outputs at least one of the operation code OPCD, the row address RADD, the page buffer control signals PBSIG, and the column address CADD in response to the command CMD and the address ADD. For example, when the command CMD input to the control circuit 180 corresponds to a program operation, the control circuit 180 controls the peripheral circuit 170 to perform the program operation on a memory block selected by the address ADD. When the command CMD input to the control circuit 180 corresponds to a read operation, the control circuit 180 controls the peripheral circuit 170 to perform the read operation on the memory block selected by the address ADD and output read data. When the command CMD input to the control circuit 180 corresponds to an erase operation, the control circuit 180 controls the peripheral circuit 170 to perform the erase operation on the selected memory block.

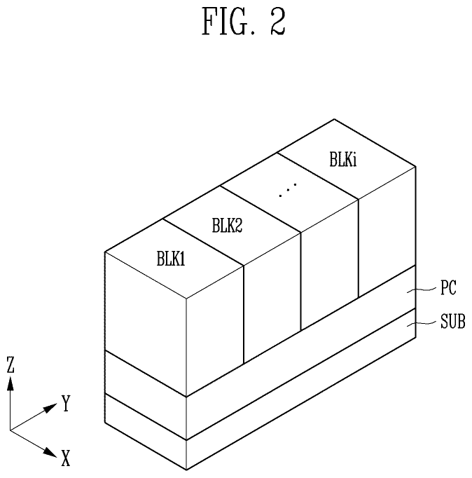

FIG. 2 is a diagram illustrating memory blocks of the memory device 100 according to an embodiment of the present disclosure.

Referring to FIG. 2, the memory device 100 includes the memory blocks BLK1 through BLKi disposed on a peripheral circuit structure PC that is disposed on a substrate SUB. The memory blocks BLK1 through BLKi at least partially overlap the peripheral circuit structure PC.

The substrate SUB may be a single crystal semiconductor layer. For example, the substrate SUB may be a bulk silicon substrate, a silicon-on-insulator substrate, a germanium substrate, a germanium-on-insulator substrate, a silicon-germanium substrate, or an epitaxial thin film formed through a selective epitaxial growth method.

The peripheral circuit structure PC includes, for example, the peripheral circuit 170 including the row decoder 130, the column decoder 150, the page buffer group 140, and the control circuit 180 that controls the operation of the memory blocks BLK1 through BLKi. For example, the peripheral circuit structure PC may include an NMOS transistor, a PMOS transistor, a resistor, and a capacitor that are electrically coupled to the memory blocks BLK1 through BLKi. The peripheral circuit structure PC is disposed between the substrate SUB and the memory blocks BLK1 to BLKi in the example of FIG. 2.

Each of the memory blocks BLK1 through BLKi includes a source structure, bit line, cell strings that are electrically coupled to the source structure and the bit lines, word lines that are electrically coupled to the cell strings, and select lines that are electrically coupled to the cell strings. Each of the cell strings include memory cells and select transistors that are coupled in series by a cell plug. Each of the select lines serves as a gate electrode of a corresponding select transistor, and each of the word lines serves as a gate electrode of a corresponding memory cell.

In another embodiment, the substrate SUB, the peripheral circuit structure PC, and the memory blocks BLK1 through BLKi may be stacked in a reverse order with respect to the order shown in FIG. 2. For example, the peripheral circuit structure PC may be disposed over the memory blocks BLK1 through BLKi.

In another embodiment, contrary to FIG. 2, the peripheral circuit structure PC may be disposed over some areas of the substrate SUB that may not overlap the memory blocks BLK1 through BLKi. For example, the peripheral circuit structure PC and the memory blocks BLK1 through BLKi may be disposed in areas of the substrate SUB that do not overlap each other.

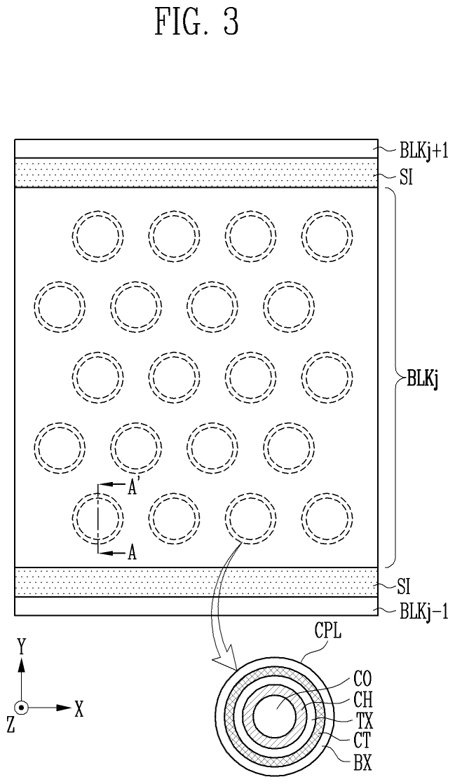

FIG. 3 is a plan view illustrating a layout of a memory device according to an embodiment of the present disclosure.

Referring to FIG. 3, the jth memory block BLKj and the nearest memory blocks (memory block BLKj−1 and memory block BLKj+1, partially shown in FIG. 3) are separated by slits SI, where j is a positive integer less than i. For example, the slits SI are disposed or extend along an X direction of the jth memory block BLKj and are adjacent to two different memory blocks, for example, memory block BLKj and memory block BLKj−1 or memory block BLKj and memory block BLKj+1 that are disposed in the Y direction. A slit SI is interposed between consecutive memory blocks.

Each of the memory blocks BLK1 through BLKi, including the jth memory block BLKj, includes a plurality of cell plugs CPL. The cell plugs CPL extend in a in a Z direction as relative to a substrate such as the substrate SUB of FIG. 2. The cell plugs CPL may be arranged in a plurality of rows or columns. Each of the plurality of rows includes the cell plugs CPL spaced apart from each other in the X direction as shown in the example of FIG. 3. The plurality of rows are spaced apart from each other in the Y direction. The center of each of the cell plugs CPL included in an odd-numbered row is offset from the center of each of the cell plugs CPL included in an even-numbered row may be offset from each other. In other words, the centers of the cell plugs CPL in consecutive rows are offset from each other.

Each of the cell plugs CPL includes a blocking layer BX, a charge trap layer CT, a tunnel isolation layer TX, a channel layer CH, and a core pillar CO. The blocking layer BX may have a cylindrical shape. The charge trap layer CT contacts an inner surface of the blocking layer BX. The tunnel isolation layer TX contacts an inner surface of the charge trap layer CT. The channel layer CH contacts an inner surface of the tunnel isolation layer TX. The core pillar CO fills an inside of the channel layer CH or is surrounded by the channel layer CH. For example, the core pillar CO may have a cylindrical shape in an area surrounded by the channel layer CH. A capping layer (not shown) may optionally be formed over the core pillar CO.

The blocking layer BX and the tunnel isolation layer TX may each include an oxide layer (for example, a silicon oxide layer), an oxynitride layer (for example, a silicon oxynitride layer), or a combination thereof. The charge trap layer CT may include a nitride layer or a variable resistance material. The channel layer CH may include an undoped silicon layer or a doped silicon layer. The core pillar CO may include an insulating layer or a conductive layer. Each of the blocking layer BX, the charge trap layer CT, the tunnel isolation layer TX, the channel layer CH, and the core pillar CO included in each of the cell plugs CPL extends in the Z direction relative to the drawing.

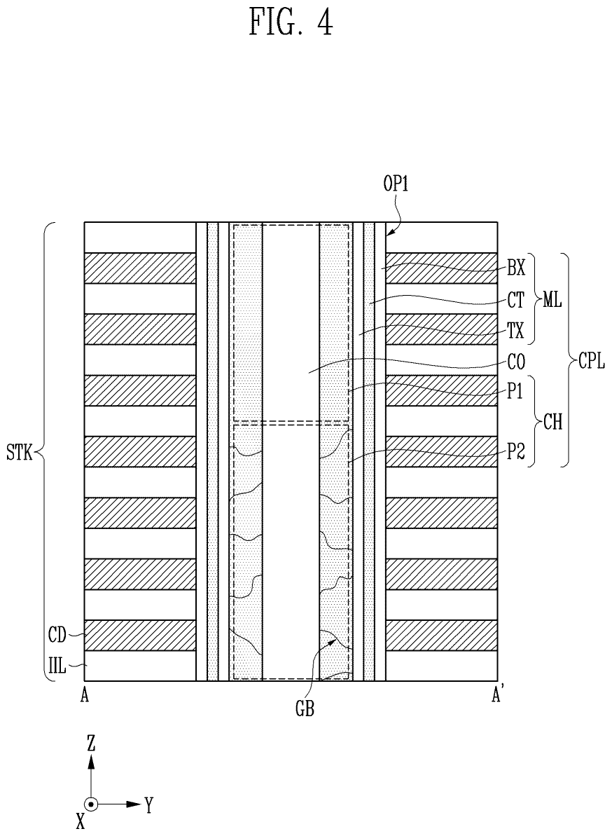

FIG. 4 is a cross-sectional view of the memory device 100 according to an embodiment of the present disclosure. FIG. 4 shows a cross-section taken along line A-A′ of FIG. 3.

Referring to FIG. 4, the memory device 100 (for example, the ith memory block BLKi) includes a stack structure STK. The stack structure STK includes a plurality of gate conductive layers CD alternately stacked with a plurality of interlayer insulating layers IIL. The gate conductive layers CD are alternately stacked with the interlayer insulating layers IIL in the Z direction as shown in FIG. 4. The gate conductive layers CD may include at least one of tungsten (W), cobalt (Co), nickel (Ni), molybdenum (Mo), silicon (Si), and polysilicon (poly-Si). The interlayer insulating layers IIL may include an oxide layer, for example, a silicon oxide layer. Each of the gate conductive layers CD corresponds to one of the drain select line DSL, the word lines WLs, and the source select line SSL of FIG. 1.

The memory device 100, such as, the ith memory block BLKi, includes the cell plug CPL. The cell plug CPL penetrates the stack structure STK. For example, the cell plug CPL is located inside a first opening OP1 penetrating the stack structure STK. The cell plug CPL extends in the Z direction as shown in FIG. 4. The memory cells or the select transistors described in FIG. 1 and FIG. 2 are formed at intersections (not shown) of the cell plug CPL and the gate conductive layers CD.

The cell plug CPL includes a memory layer ML. The memory layer ML includes the blocking layer BX, the charge trap layer CT, and the tunnel isolation layer TX. The memory layer ML penetrates or extends through the stack structure STK. The memory layer ML is formed along an inner wall of the first opening OP1. For example, the blocking layer BX contacts an inner surface of the first opening OP1. Thus, the memory layer ML contacts an inner wall of the stack structure STK. The memory layer ML extends along an outer surface of the channel layer CH. For example, the tunnel isolation layer TX contacts the outer surface of the channel layer CH.

The cell plug CPL includes the core pillar CO. The core pillar CO fills or is surrounded by the inside of the channel layer CH. The core pillar CO contacts an inner surface of the channel layer CH. The core pillar CO is surrounded by the channel layer CH.

The cell plug CPL includes the channel layer CH. The channel layer CH penetrates or extends through the stack structure STK. The channel layer CH extends in the Z direction. The channel layer CH may have a cylindrical shape. The channel layer CH includes a first part P1 and a second part P2 as shown in the example of FIG. 4. The second part P2 is located under the first part P1. A lower surface of the first part P1 contacts an upper surface of the second part P2. A first end, such as the upper surface, of the second part P2 is adjacent to a first end, such as the lower surface, of the first part. In the present disclosure, the first part P1 and the second part P2 are described as separate or divided from each other for convenience of description, although the first part P1 and the second part P2 may not be physically separated from each other and may comprise a single unified structure. For example, an interface between the first part P1 and the second part P2 may be undetectable.

The first part P1 of the channel layer CH includes single crystalline silicon in this embodiment. In the first part P1, a grain boundary GB may not be present or may be small enough to be undetectable.

The second part P2 of the channel layer CH includes polycrystalline silicon in this embodiment. The second part P2 of the channel layer CH includes one or more grain boundaries GB. The second part P2 includes polycrystalline silicon including a plurality of grains in this embodiment. Accordingly, the grain boundaries GB are located in the second part P2 of the channel layer CH. A size of the grains included in the second part P2 may not be limited to the embodiment shown in FIG. 4. FIG. 4 only shows the grain boundaries GB formed in the second part P2, although the locations and the shapes of the grain boundaries GB are not limited to the locations and the shapes of the grain boundaries GB shown in FIG. 4.

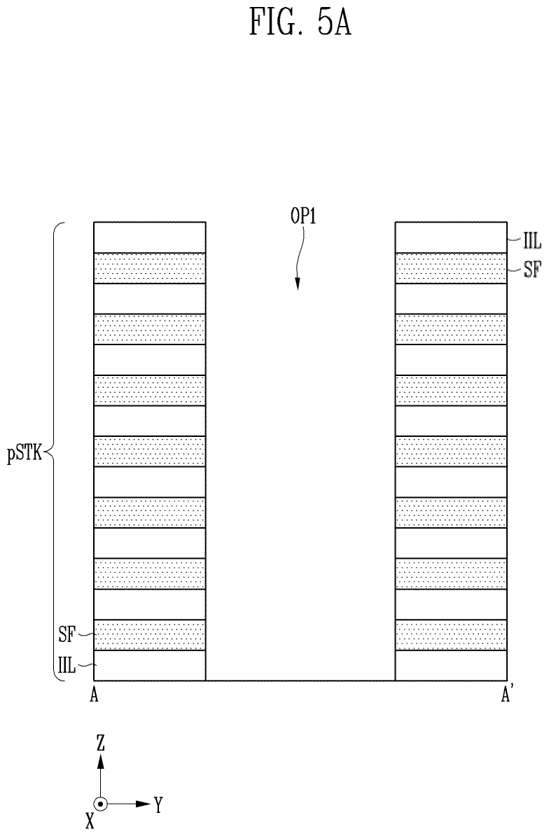

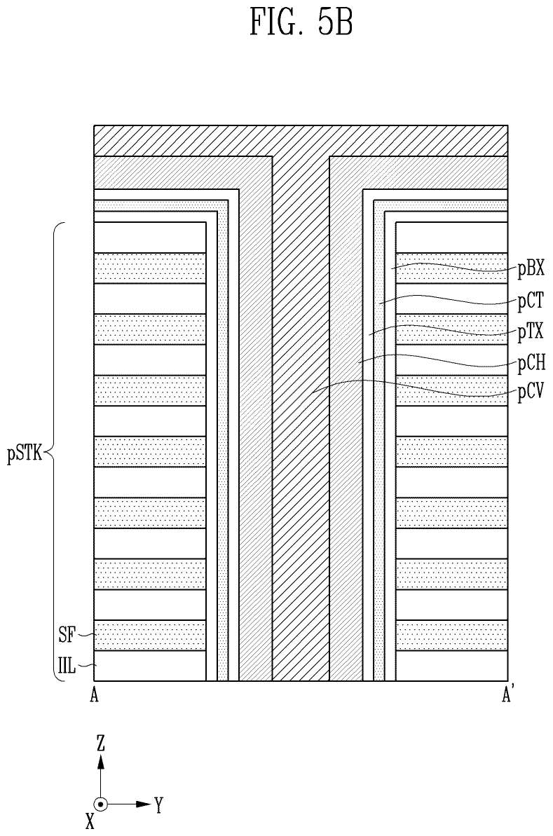

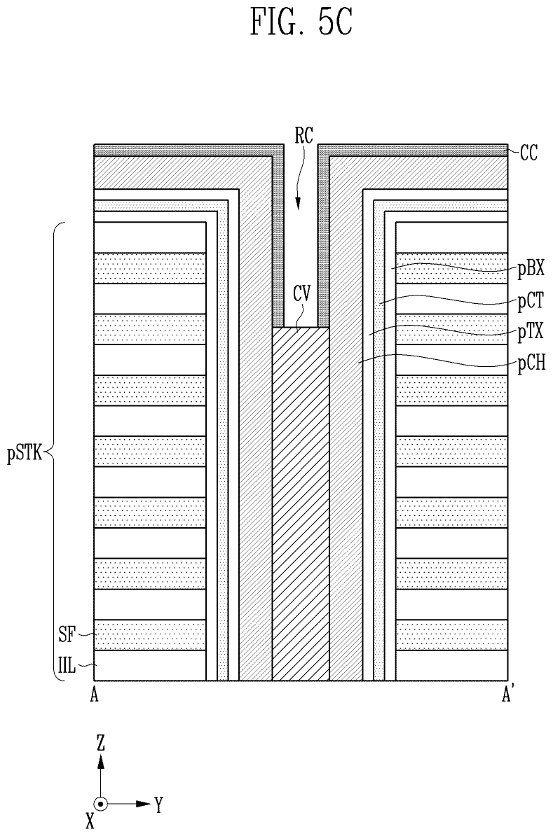

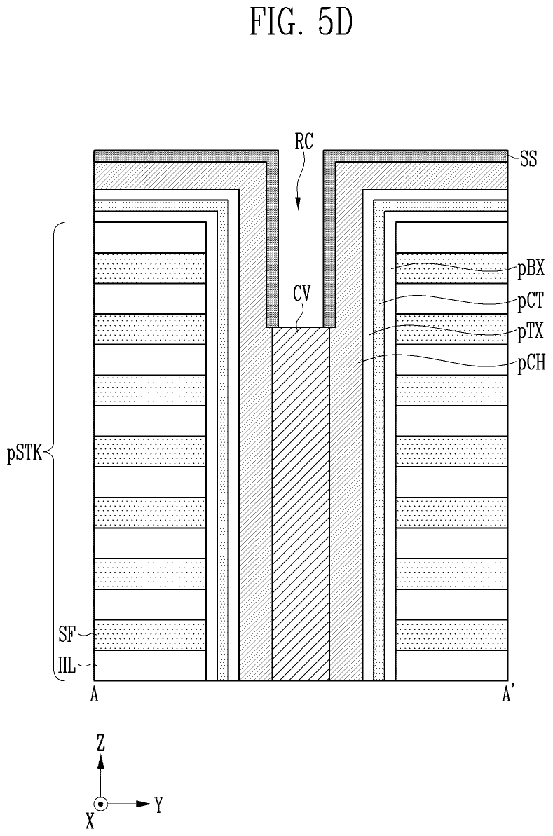

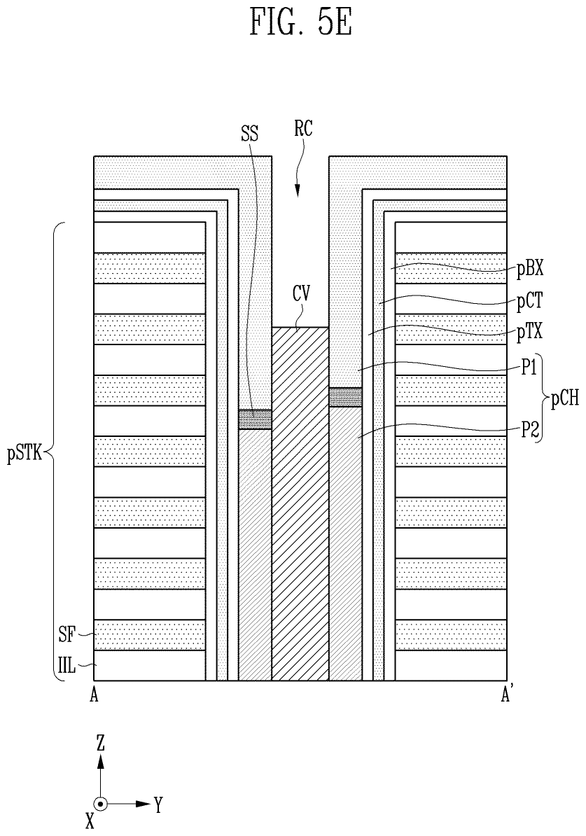

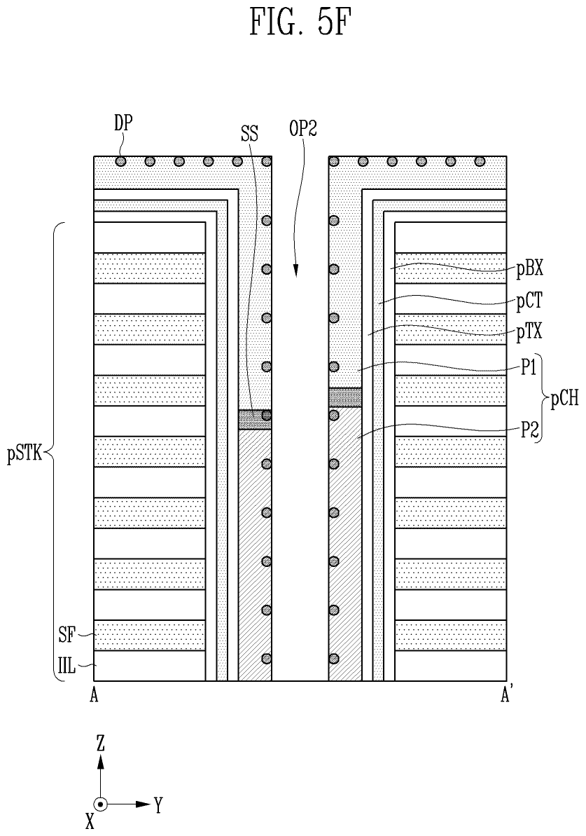

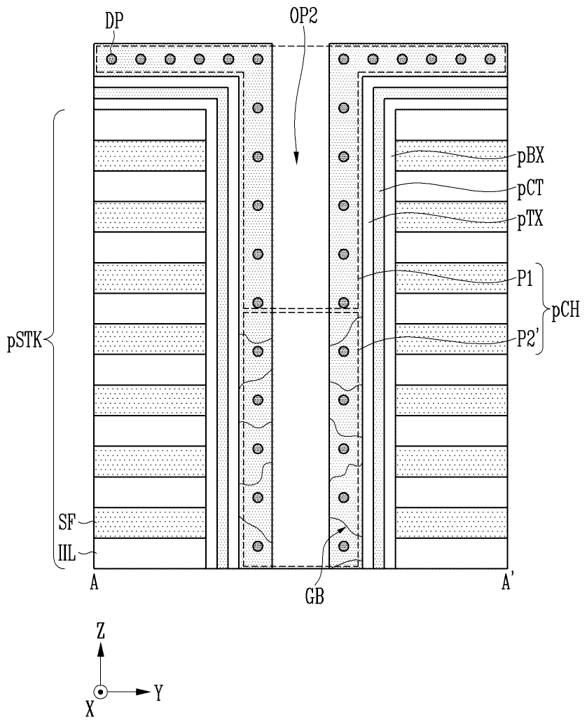

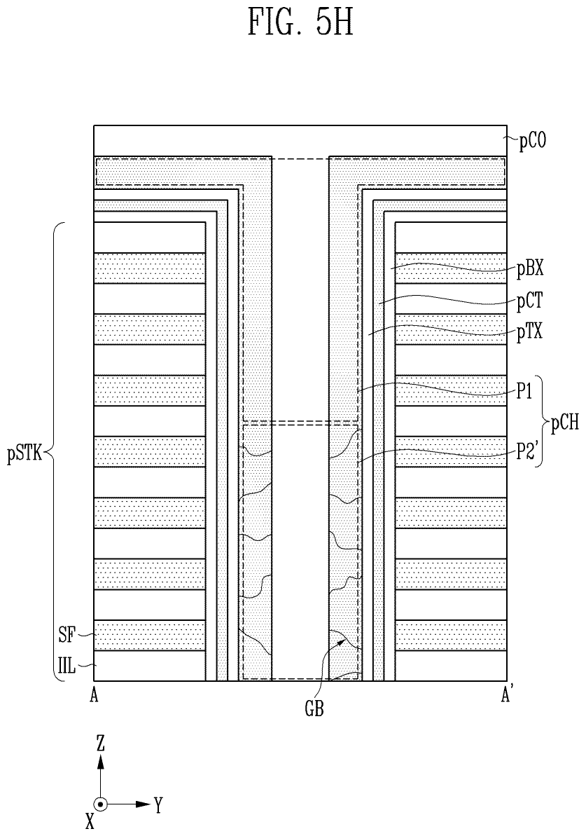

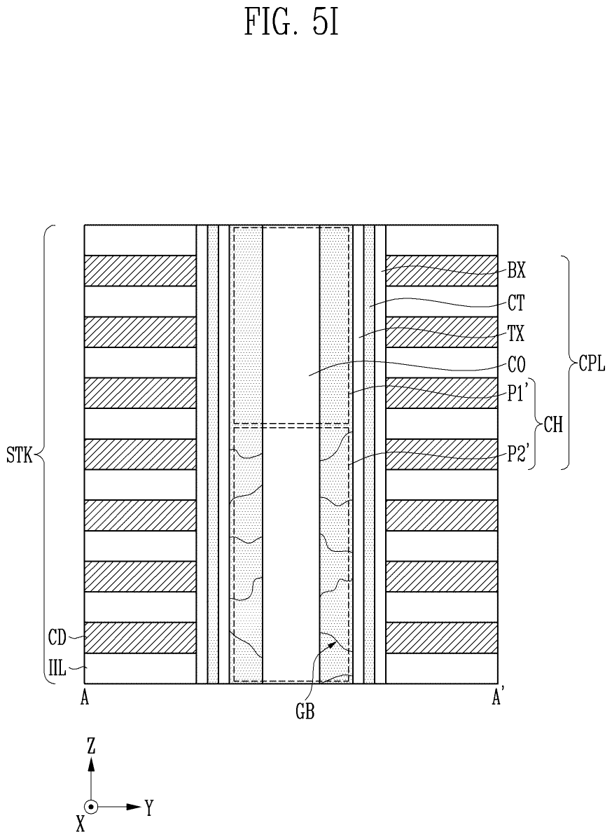

FIG. 5A through FIG. 5I are diagrams illustrating cross-sectional views of a memory device formed utilizing a method of manufacturing a memory device according to an embodiment of the present disclosure. FIG. 5A through FIG. 5I each show a cross-section taken along line A-A′ of FIG. 3.

Referring to FIG. 5A, a preliminary stack structure pSTK is formed. The preliminary stack structure pSTK includes first material layers IIL alternatively stacked with second material layers SF in the Z direction. The first material layer IIL may include an insulating material. For example, the first material layer IIL may include an oxide layer (for example, a silicon oxide layer). The second material layer SF may include a material that may be selectively removed in a subsequent process. Accordingly, the second material layer SF may include a material having an etch selectivity different from that of the first material layer IIL. For example, the second material layer SF may include a nitride layer.

The first opening OP1 penetrating the preliminary stack structure pSTK is formed. The first opening OP1 penetrates or extends through the first material layers IIL and the second material layers SF of the preliminary stack structure pSTK. The first opening OP1 extends in the Z direction. The first opening OP1 may, for example, have a circular, elliptical, conical, triangular, or rectangular shape.

Referring to FIG. 5B, a preliminary blocking layer pBX, a preliminary charge trap layer pCT, a preliminary tunnel isolation layer pTX, and a preliminary channel layer pCH are formed over the preliminary stack structure pSTK. For example, the preliminary blocking layer pBX, the preliminary charge trap layer pCT, the preliminary tunnel isolation layer pTX, and the preliminary channel layer pCH are sequentially formed on an upper surface of the preliminary stack structure pSTK and an inner surface of the preliminary stack structure pSTK surrounding or adjacent to the first opening OP1. Accordingly, the preliminary channel layer pCH is formed on the inner surface of the first opening OP1 and the upper surface of the preliminary stack structure pSTK.

The preliminary blocking layer pBX, the preliminary charge trap layer pCT, the preliminary tunnel isolation layer pTX, and the preliminary channel layer pCH are sequentially or consecutively located from an inner wall of the preliminary stack structure pSTK surrounding the first opening OP1. The preliminary blocking layer pBX, the preliminary charge trap layer pCT, the preliminary tunnel isolation layer pTX, and the preliminary channel layer pCH extend through the preliminary stack structure pSTK.

In FIG. 5B, the preliminary channel layer pCH includes, for example, amorphous silicon. The preliminary channel layer pCH may be formed by a process including depositing amorphous silicon on the upper surface of the preliminary stack structure pSTK and the inner wall of the preliminary stack structure pSTK surrounding the first opening OP1.

A preliminary cover layer pCV is formed over the preliminary channel layer pCH. The preliminary cover layer pCV fills an inside of or is disposed between the walls of the preliminary channel layer pCH. Within the first opening OP1, the preliminary cover layer pCV covers at least part of an inner surface of the preliminary channel layer pCH. In addition, the preliminary cover layer pCV covers at least part of an upper surface of the preliminary channel layer pCH formed over the preliminary stack structure pSTK. In another embodiment, the preliminary cover layer pCV may fill the first opening OP1 and may not be formed over the preliminary stack structure pSTK. The preliminary cover layer pCV may include an oxide layer.

Referring to FIG. 5C, a portion or section of the preliminary cover layer pCV is removed to form a cover layer CV. For example, an upper portion of the preliminary cover layer pCV may be etched to form a recess RC over an upper portion of the cover layer CV. A portion of the inner surface of the preliminary channel layer pCH is exposed after the section of the preliminary cover layer pCV is removed. The portion of the inner surface of the preliminary channel layer pCH is exposed through the recess RC. For example, the cover layer CV covers a lower portion of the inner surface of the preliminary channel layer pCH and does not cover an upper portion of the inner surface of the preliminary channel layer pCH. Accordingly, the upper portion of the inner surface of the preliminary channel layer pCH is exposed through the recess RC. In addition, the upper surface of the preliminary channel layer pCH formed over the preliminary stack structure pSTK is exposed. A wet etching process, a dry etching process, or the like may be performed to selectively etch or remove part of the preliminary cover layer pCV.

A conductive layer CC is formed over the preliminary channel layer pCH exposed through the recess RC. The conductive layer CC covers a portion of the preliminary channel layer pCH that is not covered by the cover layer CV. For example, the conductive layer CC is formed on the upper surface of the preliminary channel layer pCH that is located over the preliminary stack structure pSTK. In addition, the conductive layer CC is formed on the portion, for example, the upper portion, of the inner surface of the preliminary channel layer pCH that is located within the first opening OP1. The conductive layer CC may include a metal such as nickel (Ni).

Referring to FIG. 5D, the conductive layer CC may be converted into a silicide layer SS. The conductive layer CC is converted into the silicide layer SS through a first heat treatment. The conductive layer CC contacting a surface of the preliminary channel layer pCH is converted into the silicide layer SS. The silicide layer SS may include silicide such as nickel silicide (NiSi₂).

Referring to FIG. 5E, a portion of the preliminary channel layer pCH may be crystallized using the silicide layer SS. The portion of the preliminary channel layer pCH is converted into single crystalline silicon using the silicide layer SS. The crystallization of the preliminary channel layer pCH using the silicide layer SS is induced during a second heat treatment, for example. The crystallization of the preliminary channel layer pCH using the silicide layer SS is referred to as a metal-induced lateral recrystallization (MILC) method or process.

In FIG. 5D, the silicide layer SS contacts an upper portion of the preliminary channel layer pCH. Accordingly, during the metal-induced lateral recrystallization (MILC) as shown in FIG. 5E, crystallization proceeds from the upper portion towards the lower portion of the preliminary channel layer pCH relative to the drawing. For example, the silicide layer SS moves in a downward direction relative to the drawing, for example, the negative Z direction, when the second heat treatment is performed. Accordingly, the upper portion of the preliminary channel layer pCH is crystallized before the lower portion of the preliminary channel layer pCH. As a result, as shown in FIG. 5E, the upper portion of the preliminary channel layer pCH includes single crystalline silicon and the lower portion of the preliminary channel layer pCH includes amorphous silicon.

A portion of the preliminary channel layer pCH that is crystallized by using the silicide layer SS is referred to as the first part P1 or the first part P1 of the preliminary channel layer pCH. The first part P1 crystallized by the MILC method includes single crystalline silicon. The portion of the preliminary channel layer pCH located over or above the silicide layer SS after the second heat treatment is performed is referred to as the first part P1. Another portion of the preliminary channel layer pCH located under or below the silicide layer SS relative to the figure is referred to as the second part P2 or the second part P2 of the preliminary channel layer pCH. The silicide layer SS is located between the first part P1 and the second part P2 of the preliminary channel layer pCH. In FIG. 5E, the first part P1 may include single crystalline silicon and the second part P2 includes amorphous silicon. When crystallization of the preliminary channel layer pCH using the silicide layer SS is induced, the silicide layer SS moves in the downward direction relative to the drawing. The lower surface of the first part P1 may be located below an upper surface of the cover layer CV, for example, in the negative Z direction.

Referring to FIG. 5E, a height of the silicide layer SS, for example, a location of the silicide layer SS in the Z direction, may vary with respect to the X direction and/or the Y direction or the X-Y plane. When the second heat treatment is performed, a speed of movement of the silicide layer SS may vary depending on a location of the silicide layer SS in the X-Y plane. Accordingly, the silicide layer SS may be formed at different heights or locations in the Z direction on the preliminary channel layer pCH within any of the cell plugs CPL. For example, as shown in FIG. 5E, the silicide layer SS on the left side of the drawing is lower than the silicide layer SS on the right side of the drawing in the Z direction.

Referring to FIG. 5F, the cover layer CV is removed to form a second opening OP2. The inner surface of the preliminary channel layer pCH is exposed through the second opening OP2. Accordingly, both the upper surface and the inner surface of the preliminary channel layer pCH are exposed.

The preliminary channel layer pCH is doped with a conductive material DP. The conductive material DP is doped into the upper surface and the inner surface of the preliminary channel layer pCH in the example of FIG. 5F. For example, the inner surface of the preliminary channel layer pCH is doped with the conductive material DP through the second opening OP2. The conductive material DP may include a metal such as nickel (Ni).

The first part P1 of the preliminary channel layer pCH is doped with the conductive material DP. In addition, the second part P2 of the preliminary channel layer pCH is doped with the conductive material DP. The processes of doping the conductive material DP into the first part P1 and into the second part P2 may be performed simultaneously.

The conductive material DP is doped not only into the second part P2 including amorphous silicon but also into the first part P1 including single crystalline silicon. Thus, the conductive material DP is doped not only into the second part P2 to facilitate crystallization, but also into the first part P1 that is already crystallized. In addition, a portion of the conductive material DP may be doped into the silicide layer SS.

Referring to FIG. 5G, the preliminary channel layer pCH is crystallized using the conductive material DP. A second part P2′ of the preliminary channel layer pCH is converted into polycrystalline silicon. The crystallization of the preliminary channel layer pCH, for example, the second part P2′, using the conductive material DP is induced using a third heat treatment. The crystallization of the preliminary channel layer pCH using the conductive material DP is referred to as a metal-induced recrystallization (MIC) method or process.

The second part P2′ of the preliminary channel layer pCH may be crystallized based on a location where the conductive material DP is doped. For example, the second part P2′ may be crystallized around or near the location where the conductive material DP is doped. Accordingly, the crystallized second part P2′ includes a plurality of grains. The second part P2′ of the preliminary channel layer pCH includes the grain boundaries GB.

Although the conductive material DP is doped into the first part P1 of the preliminary channel layer pCH, because the first part P1 includes single crystalline silicon, a crystalline state of P1 does not necessarily change.

The silicide layer SS is diffused into the preliminary channel layer pCH when the third heat treatment is performed. For example, a metal material included in the silicide layer SS may be used in crystallization using a metal-induced recrystallization (MIC) method. Accordingly, the silicide layer SS may be undetectable, as shown in FIG. 5G.

Referring to FIG. 5H, the conductive material DP in the preliminary channel layer pCH is removed. In addition, the remaining materials included in the conductive layer CC shown in FIG. 5 may advantageously be removed with the conductive material DP.

The preliminary channel layer pCH from which the conductive material DP is removed includes the first part P1 including single crystalline silicon and the second part P2′ including polycrystalline silicon. The first part P1 is located over the second part P2′ relative to the drawing.

A preliminary core pillar pCO is formed in the second opening OP2. At least a portion of the preliminary core pillar pCO is surrounded by the preliminary channel layer pCH. Another portion of the preliminary core pillar pCO is optionally formed over the preliminary stack structure pSTK. The preliminary core pillar pCO contacts the upper surface and the inner surface of the preliminary channel layer pCH in this example.

Referring to FIG. 5I, the preliminary core pillar pCO, the preliminary channel layer pCH, the preliminary tunnel isolation layer pTX, the preliminary charge trap layer pCT, and the preliminary blocking layer pBX located over or above the preliminary stack structure pSTK in the Z direction are removed. Accordingly, the upper surface of the preliminary stack structure pSTK is exposed.

The blocking layer BX, the charge trap layer CT, the tunnel isolation layer TX, and the channel layer CH that remain after the material layers are removed from above the preliminary stack structure pSTK constitute the cell plug CPL. In addition, the channel layer CH may include a first part P1′ having a cylindrical shape and the second part P2′ extending below or downwards from the first part P1′. The first part P1′ includes single crystalline silicon and the second part P2′ includes single polycrystalline silicon.

The second material layers SF are replaced by third material layers CD to form the stack structure STK. The third material layers CD include a conductive material.

When the channel layer CH is formed according to an embodiment of the present disclosure, a grain size of the silicon included in the channel layer CH may be increased. Compared to the example where a channel layer is formed using any one of the metal-induced lateral recrystallization (MILC) method and the metal-induced recrystallization (MIC), the silicon included in the channel layer CH according the embodiment of the present disclosure may have a greater grain size. For example, because the channel layer CH of the present disclosure not only includes the second part (P2, P2′) including amorphous silicon but also the first part (P1, P1′) including single crystalline silicon, the channel layer CH may have a greater average grain size than a channel layer including only amorphous silicon. As the grain size of the silicon included in the channel layer CH increases, the resistance of the grain boundary GB included in the channel layer CH decreases. According to the present disclosure, the amount of the current flowing in the memory cells in the memory device 100 may be increased.

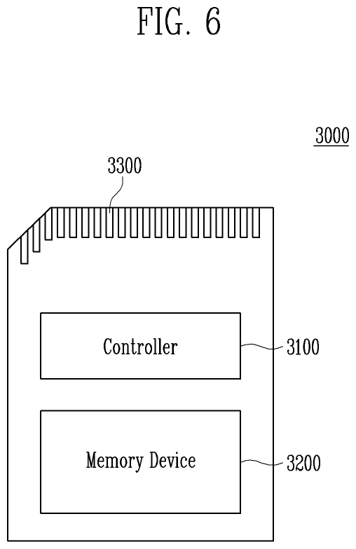

FIG. 6 is a diagram illustrating an embodiment of a memory card system 3000 including a memory device 3200 according to the present disclosure.

Referring to FIG. 6, the memory card system 3000 includes a controller 3100, the memory device 3200, and a connector 3300.

The controller 3100 is coupled to the memory device 3200. The controller 3100 is configured to access the memory device 3200. For example, the controller 3100 is configured to control a program operation, a read operation, an erase operation, and a background operation of the memory device 3200. The controller 3100 is configured to provide an interface between the memory device 3200 and a host. The controller 3100 is configured to drive firmware that controls the memory device 3200. For example, the controller 3100 may include components such as a Random Access Memory (RAM), a processing unit, a host interface, a memory interface, and an error corrector.

The controller 3100 communicates with an external device through the connector 3300. The controller 3100 communicates with the external device, for example, the host, according to a specific communication protocol. For example, the controller 3100 may be configured to communicate with the external device through at least one of various communication protocols such as Universal Serial Bus (USB), Multi-Media Card (MMC), embedded MMC (eMMC), Peripheral Component Interconnection (PCI), PCI express (PCI-E), Advanced Technology Attachment (ATA), Serial-ATA (SATA), Parallel-ATA (PATA), Small Computer System Interface (SCSI), Enhanced Small Disk Interface (ESDI), Integrated Drive Electronics (IDE), Firewire, Universal Flash Storage (UFS), Wi-Fi, Bluetooth, and NVMe protocols. For example, the connector 3300 may be configured according to at least one of the above communication protocols.

The memory device 3200 includes a plurality of memory cells configured, for example in the same manner as the memory device 100 shown in FIG. 1 and formed utilizing the method of manufacturing a memory device according to the method described above with reference to FIG. 5A through FIG. 5I.

The controller 3100 and the memory device 3200 are integrated into a single semiconductor device to constitute a memory card. For example, the controller 3100 and the memory device 3200 may constitute a memory card such as a personal computer (PC) card (Personal Computer Memory Card International Association (PCMCIA)), a Compact Flash (CF) card, a Smart Media Card (SM or SMC), a memory stick, a Multi-Media Card (MMC, RS-MMC, MMCmicro, or eMMC), an SD card (SD, miniSD, microSD, or SDHC), or a Universal Flash Storage (UFS).

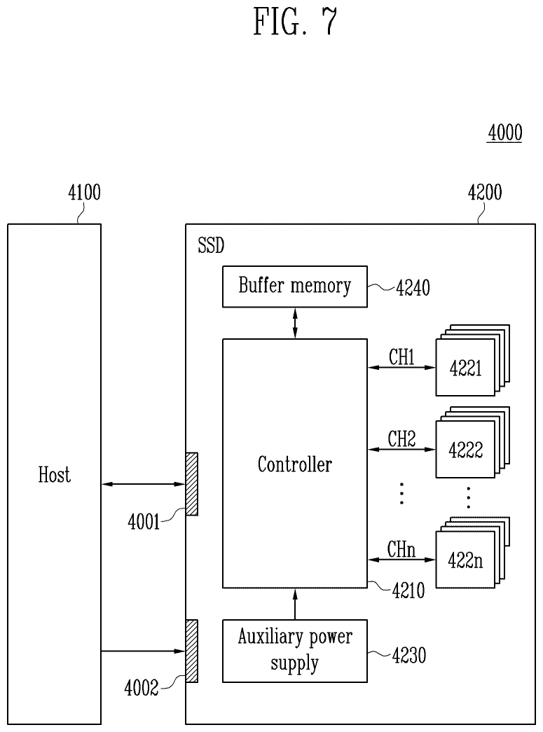

FIG. 7 is a diagram illustrating an embodiment of a solid state drive (SSD) system 4000 including a plurality of memory devices 4221 to 422n according to the present disclosure.

Referring to FIG. 7, the SSD system 4000 includes a host 4100 and an SSD 4200. The SSD 4200 exchanges a signal with the host 4100 through a signal connector 4001 and receives power through a power connector 4002. The SSD 4200 includes a controller 4210, the plurality of memory devices 4221 to 422n, an auxiliary power supply 4230, and a buffer memory 4240.

The controller 4210 controls the plurality of memory devices 4221 to 422n in response to signals received from the host 4100. For example, the signals may be based on an interface between the host 4100 and the SSD 4200. For example, the signals may be configured or constructed according to at least one of a plurality of interfaces such as Universal Serial Bus (USB), Multi-Media Card (MMC), embedded MMC (eMMC), Peripheral Component Interconnection (PCI), PCI express (PCI-E), Advanced Technology Attachment (ATA), Serial-ATA (SATA), Parallel-ATA (PATA), Small Computer System Interface (SCSI), Enhanced Small Disk Interface (ESDI), an Integrated Drive Electronics (IDE), Firewire, Universal Flash Storage (UFS), Wi-Fi, Bluetooth, and NVMe interfaces.

The plurality of memory devices 4221 to 422n each include a plurality of memory cells configured to store data. Each of the plurality of memory devices 4221 to 422n is configured in the same manner as the memory device 100 shown in FIG. 1 and formed utilizing the method of manufacturing a memory device according to the method described above with reference to FIG. 5A through FIG. 5I. The plurality of memory devices 4221 to 422n communicates with the controller 4210 through channels CH1 through CHn.

The auxiliary power supply 4230 is coupled to the host 4100 through a power connector 4002. The auxiliary power supply 4230 receives power input from the host 4100 and may adjust the power according to the needs of the SSD. When the supply of power from the host 4100 is not smooth or consistent, the auxiliary power supply 4230 provides power to the SSD 4200. For example, the auxiliary power supply 4230 may be located inside or outside the SSD 4200. For example, the auxiliary power supply 4230 may be located on a main board and provide auxiliary power to the SSD 4200.

The buffer memory 4240 serves as a buffer memory for the SSD 4200. For example, the buffer memory 4240 temporarily stores data received from the host 4100 or data received from the plurality of memory devices 4221 to 422n or may temporarily store metadata, for example, mapping tables, of the memory devices 4221 to 422n. The buffer memory 4240 may include volatile memories such as DRAM, SDRAM, DDR SDRAM, and LPDDR SDRAM, or non-volatile memories such as FRAM, ReRAM, STT-MRAM, and PRAM.

According to embodiments of the present disclosure, a current flowing in memory cells may be increased by increasing a grain size of silicon included in a channel layer of a semiconductor device. According to an embodiment, a method may include three separate heat treatments. According to an embodiment, a further may include forming a conductive layer on an exposed inner surface of the channel layer; converting the conductive layer into a silicide layer using a heat treatment; inducing first crystallization of the first part using the silicide layer during a second heat treatment; and converting the second part into polycrystalline silicon comprises using a third heat treatment.

Concepts in conjunction with various embodiments are described above. Those skilled in the art will understand that various modifications, additions, and substitutions are possible, without departing from the scope and spirit of the present disclosure. Accordingly, the embodiments disclosed in the present specification should be considered not from a restrictive standpoint but rather from an illustrative standpoint. Therefore, the scope of the present disclosure should not be limited to the foregoing embodiments. All changes within the meaning and range of equivalency of the claims are to be included within their scope.

What is claimed is:

1. A method of manufacturing a memory device, the method comprising:
forming a stack structure including first material layers alternately stacked with second material layers;
forming a channel layer including amorphous silicon in an opening extending through the stack structure;
converting a first part of the channel layer into single crystalline silicon;
doping the first part of the channel layer with a conductive material;
doping a second part of the channel layer with the conductive material, wherein the second part is different from the first part; and
converting the second part of the channel layer into polycrystalline silicon using the conductive material.

2. The method of claim 1, wherein the forming the channel layer comprises:
forming the opening extending through the stack structure;
forming a memory layer on an inner surface of the stack structure surrounding the opening and an outer surface of the stack structure; and
forming the channel layer on the memory layer.

3. The method of claim 2, wherein, during the forming of the channel layer on the memory layer, the channel layer is formed on the inner surface of the stack structure surrounding the opening and the outer surface of the stack structure, wherein the outer surface of the stack structure and the inner surface of the stack structure are on consecutive sides of the stack structure.

4. The method of claim 1, wherein converting the first part into the single crystalline silicon comprises:
forming a cover layer such that a portion of an inner surface of the channel layer is exposed through a recess;
forming a conductive layer on the exposed inner surface of the channel layer; and
converting the first part into the single crystalline silicon using the conductive layer.

5. The method of claim 4, wherein forming the cover layer comprises:
forming a preliminary cover layer inside the channel layer; and
forming the recess by removing a portion of the preliminary cover layer;
wherein the portion of the inner surface of the channel layer is exposed through the recess.

6. The method of claim 4, wherein converting the first part into single crystalline silicon using the conductive layer comprises:
converting the conductive layer into a silicide layer using a first heat treatment; and
inducing crystallization of the first part by using the silicide layer during a second heat treatment.

7. The method of claim 6, wherein the silicide layer moves toward the cover layer during the second heat treatment.

8. The method of claim 4, wherein a first surface of the cover layer is adjacent to the recess, and the first surface of the cover layer is disposed between the recess and a first end of the first part of the channel layer as formed during converting of the first part into the single crystalline silicon using the conductive layer.

9. The method of claim 1, wherein doping the first part with the conductive material and doping the second part with the conductive material are performed simultaneously.

10. The method of claim 1, wherein converting the second part comprises using a third heat treatment.

11. The method of claim 1, wherein a first end of the second part is formed adjacent to a first end of the first part.

12. The method of claim 1, further comprising, after converting the second part into polycrystalline silicon, removing the conductive material from the channel layer.

13. A memory device, comprising:
a stack structure; and
a channel layer formed in an opening extending through the stack structure,
wherein the channel layer includes a first part including single crystalline silicon and a second part including polycrystalline silicon, wherein the first part is adjacent to the second part.

14. The memory device of claim 13, further comprising a memory layer formed in the opening extending through the stack structure and extending along an outer surface of the channel layer.

15. The memory device of claim 14, wherein the memory layer comprises:
a blocking layer contacting an inner surface of the stack structure;
a charge trap layer contacting an inner surface of the blocking layer; and
a tunnel isolation layer contacting an inner surface of the charge trap layer and the outer surface of the channel layer.

16. The memory device of claim 13, further comprising a core pillar inside the channel layer.

17. A method comprising:
forming an opening extending through a stack structure;
forming a channel layer including amorphous silicon in the opening;
converting a first part of the channel layer into single crystalline silicon;
doping the first part of the channel layer and a second part of the channel layer with a conductive material, wherein the second part is adjacent to the first part; and
converting the second part of the channel layer into polycrystalline silicon using the conductive material.

18. The method of claim 17, further comprising three separate heat treatments.

19. The method of claim 17, further comprising:
forming a conductive layer on an exposed inner surface of the channel layer;
converting the conductive layer into a silicide layer using a first heat treatment;
inducing crystallization of the first part using the silicide layer during a second heat treatment; and
converting the second part into polycrystalline silicon comprises using a third heat treatment.
